(19) United States
(12) Patent Application Publication
(10) Pub. No.: US 2026/0045912 A1
(43) Pub. Date: Feb. 12, 2026

(54) Second Order Intermodulation Injection for Non-linearity Cancellation

(71) Applicant: Apple Inc., Cupertino, CA (US)

(72) Inventor: Omar E. Elaasar, San Diego, CA (US)

(21) Appl. No.: 19/087,327

(22) Filed: Mar. 21, 2025

Related U.S. Application Data
(60) Provisional application No. 63/681,414, filed on Aug. 9, 2024.

(51) Int. Cl. H03F 1/02; H03F 3/45

(52) U.S. Cl. CPC H03F 1/0211; H03F 3/45237

(57) ABSTRACT

An electronic device may include wireless circuitry. The wireless circuitry can include a first input transistor, a first capacitance neutralization having a source terminal coupled to a tail node, and a second order intermodulation generation circuit configured to produce second order intermodulation signals at the tail node. The wireless circuitry can further include a second input transistor and a second capacitance neutralization transistor having a source terminal coupled to the tail node. The first and second capacitance neutralization transistors can be cross-coupled with the input transistors. A fixed or adjustable current source can be coupled to the tail node. The second order intermodulation generation circuit can include a transistor biased in a weak inversion mode.

This application claims the benefit of U.S. Provisional Patent Application No. 63/681,414, filed Aug. 9, 2024, which is hereby incorporated by reference herein in its entirety.

### FIELD

This disclosure relates generally to electronic devices, including electronic devices with wireless communications circuitry.

### BACKGROUND

Electronic devices can have wireless communications capabilities. An electronic device with wireless communications capabilities has wireless communications circuitry with one or more antennas. Transceiver circuitry in the wireless communications circuitry uses the antennas to transmit and receive radio-frequency signals.

Radio-frequency signals transmitted by an antenna can be fed through a power amplifier, which is configured to amplify low power analog signals to higher power signals more suitable for transmission through the air over long distances. Radio-frequency signals received at an antenna can be fed through a low noise amplifier, which is configured to amplify low power analog signals to higher power signals for ease of processing at a receiver. It can be challenging to design satisfactory amplifier circuitry for an electronic device.

### SUMMARY

An aspect of the disclosure provides circuitry that includes a first input transistor having a gate terminal, a first capacitance neutralization transistor having a gate terminal shorted to the gate terminal of the first input transistor and having a source terminal coupled to a tail node, and a second order intermodulation (IM2) generation circuit configured to produce second order intermodulation (IM2) signals at the tail node. The circuitry can further include: a second input transistor having a gate terminal; a second capacitance neutralization transistor having a gate terminal shorted to the gate terminal of the second input transistor, a drain terminal coupled to the first input transistor, and a source terminal coupled to the tail node; and a current source coupled to the tail node. The current source can be a transistor or a resistor. The second order intermodulation generation circuit can include a transistor having a source terminal coupled to the tail node and having a drain terminal coupled to a positive power supply line.

An aspect of the disclosure provides circuitry that includes a first input transistor configured to receive a radio-frequency signal, a second input transistor configured to receive the radio-frequency signal, a pair of transistors cross-coupled with the first and second input transistors, and a second order intermodulation (IM2) generation circuit coupled to a virtual ground node between the pair of transistors. The circuitry can further include an adjustable current source coupled to the virtual ground node or a resistor coupled between the virtual ground node and a power supply line such as a ground line. The second order intermodulation generation circuit can include a transistor biased in a weak inversion mode. The transistor of the second order intermodulation generation circuit can be configured to receive a gate voltage having a value configured to optimize a third order intercept point for the circuitry. The second order intermodulation generation circuit can further include a resistor coupled at a gate terminal of the transistor and configured to control second order intermodulation signals produced by the second order intermodulation generation circuit.

An aspect of the disclosure provides amplifier circuitry that includes: a first transistor having a gate terminal and a source-drain terminal; a second transistor having a gate terminal and a source-drain terminal; a third transistor having a gate terminal shorted to the gate terminal of the first transistor, a first source-drain terminal coupled to the source-drain terminal of the second transistor, and a second source-drain terminal coupled to a tail node; a fourth transistor having a gate terminal shorted to the gate terminal of the second transistor, a first source-drain terminal coupled to the source-drain terminal of the first transistor, and a second source-drain terminal coupled to the tail node; and a second order intermodulation (IM2) injection transistor having a first source-drain terminal coupled to the tail node and having a second source-drain terminal coupled to a power supply line. The amplifier circuitry can further include a current source transistor or a resistor coupled to the tail node.

Further features of the disclosure, its nature and various advantages will be more apparent from the accompanying drawings and following detailed description.

### BRIEF DESCRIPTION OF THE DRAWINGS

FIG. 1 is a diagram of an illustrative electronic device having wireless circuitry in accordance with some embodiments.

FIG. 2 is a diagram of illustrative wireless circuitry in accordance with some embodiments.

FIG. 3 is a circuit diagram of illustrative differential circuitry having a second (2^{nd}) order intermodulation (IM2) generation circuit in accordance with some embodiments.

FIG. 4 is a diagram illustrating third order non-linearity cancellation in accordance with some embodiments.

FIG. 5 is a circuit diagram of an illustrative IM2 generation circuit coupled to a tail transistor in accordance with some embodiments.

FIG. 6 is a circuit diagram of an illustrative IM2 generation circuit coupled to a tail resistor in accordance with some embodiments.

FIG. 7 is a diagram plotting third order intercept point as a function of a gate voltage provided to an IM2 generation circuit in accordance with some embodiments.

FIG. 8 is a diagram showing how third order intercept point can be improved via third order non-linearity cancellation in accordance with some embodiments.

FIG. 9 is a diagram showing how amplitude modulation to amplitude modulation (AMAM) distortion can be reduced via third order non-linearity cancellation in accordance with some embodiments.

FIG. 10 is a diagram showing how amplitude modulation to phase modulation (AMPM) distortion can be reduced via third order non-linearity cancellation in accordance with some embodiments.

### DETAILED DESCRIPTION

An electronic device may be provided with wireless circuitry. The wireless circuitry can include radio-frequency amplifiers, mixers, and other transmitting or receiving circuits for processing signals in a transmit path or a receive path. An amplifier, mixer, or other components in the transmit or receive path can include one or more input transistors that, in practice, exhibit non-linear characteristics. Such transistor non-linearities can, if care is not taken, generate third order intermodulation distortion (IMD3) that degrade the signal-to-noise and distortion ratio (SNDR) and error vector magnitude (EVM) of the wireless circuitry.

To compensate such third order intermodulation distortion, the input transistors can be cross-coupled with capacitance neutralization transistors and a second order intermodulation (IM2) generation circuit coupled to source terminals of the cross-coupled capacitance neutralization transistors. The IM2 generation circuit can produce (inject) a second order intermodulation signal at the source terminals of the cross-coupled capacitance neutralization transistors, which can then be transformed into corresponding third order non-linearity components out of phase with undesired IMD3 components associated with the input transistors. Operated in this way, the IM2 generation circuit can be configured to provide third order non-linearity cancellation while providing reduction in both amplitude modulation to amplitude modulation (AMAM) distortion and amplitude modulation to phase modulation (AMPM) distortion and while preserving enhanced reverse isolation. The IM2 generation circuit configured as such can thus sometimes be considered part of a third order non-linearity cancellation circuit.

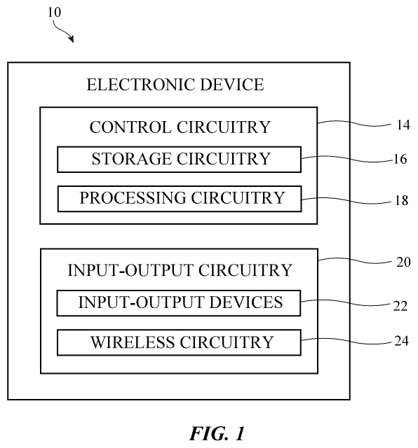

FIG. 1 is a diagram of an electronic device such as electronic device 10 that can be provided with a linearity improvement circuit such as a third (3^{rd}) order non-linearity cancellation circuit. Electronic device 10 may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the schematic diagram FIG. 1, device 10 may include components located on or within an electronic device housing such as housing 12. Housing 12, which may sometimes be referred to as a case, may be formed of plastic, glass, ceramics, fiber composites, metal (e.g., stainless steel, aluminum, metal alloys, etc.), other suitable materials, or a combination of these materials. In some situations, parts or all of housing 12 may be formed from dielectric or other low-conductivity material (e.g., glass, ceramic, plastic, sapphire, etc.). In other situations, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include on one or more microprocessors, microcontrollers, digital signal processors, host processors, baseband processor integrated circuits, application specific integrated circuits, central processing units (CPUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols-sometimes referred to as Wi-Fi®), protocols for other short-range wireless communications links such as the Bluetooth® protocol or other wireless personal area network (WPAN) protocols, IEEE 802.11ad protocols (e.g., ultra-wideband protocols), cellular telephone protocols (e.g., 3G protocols, 4G (LTE) protocols, 5G New Radio (NR) protocols, 6G protocols, etc.), MIMO protocols, antenna diversity protocols, satellite navigation system protocols (e.g., global positioning system (GPS) protocols, global navigation satellite system (GLONASS) protocols, etc.), antenna-based spatial ranging protocols (e.g., radio detection and ranging (RADAR) protocols or other desired range detection protocols for signals conveyed at millimeter and centimeter wave frequencies), or any other desired communications protocols. Each communications protocol may be associated with a corresponding radio access technology (RAT) that specifies the physical connection methodology used in implementing the protocol.

Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays, light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, electronic pencil (e.g., a stylus), and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include wireless circuitry such as wireless circuitry 24 (sometimes referred to herein as wireless communications circuitry) for wirelessly conveying radio-frequency signals. While control circuitry 14 is shown separately from wireless communications circuitry 24 for the sake of clarity, wireless communications circuitry 24 may include processing circuitry that forms a part of processing circuitry 18 and/or storage circuitry that forms a part of storage circuitry 16 of control circuitry 14 (e.g., portions of control circuitry 14 may be implemented on wireless communications circuitry 24). As an example, control circuitry 14 (e.g., processing circuitry 18) may include baseband processor circuitry or other control components that form a part of wireless communications circuitry 24.

Wireless circuitry 24 may include radio-frequency (RF) transceiver circuitry formed from one or more integrated circuits, power amplifier circuitry configured to amplify uplink radio-frequency signals (e.g., radio-frequency signals transmitted by device 10 to an external device), low-noise amplifiers configured to amplify downlink radio-frequency signals (e.g., radio-frequency signals received by device 10 from an external device), passive radio-frequency components, one or more antennas, transmission lines, and other circuitry for handling radio-frequency wireless signals. Wireless signals can also be sent using light (e.g., using infrared communications).

Wireless circuitry 24 may include radio-frequency transceiver circuitry for handling transmission and/or reception of radio-frequency signals in various radio-frequency communications bands. For example, the radio-frequency transceiver circuitry may handle wireless local area network (WLAN) communications bands such as the 2.4 GHz and 5 GHz Wi-Fi® (IEEE 802.11) bands, wireless personal area network (WPAN) communications bands such as the 2.4 GHz Bluetooth® communications band, cellular telephone communications bands such as a cellular low band (LB) (e.g., 600 to 960 MHz), a cellular low-midband (LMB) (e.g., 1400 to 1550 MHz), a cellular midband (MB) (e.g., from 1700 to 2200 MHz), a cellular high band (HB) (e.g., from 2300 to 2700 MHz), a cellular ultra-high band (UHB) (e.g., from 3300 to 5000 MHz), or other cellular communications bands between about 600 MHz and about 5000 MHz (e.g., 3G bands, 4G LTE bands, 5G New Radio Frequency Range 1 (FR1) bands below 10 GHz, 5G New Radio Frequency Range 2 (FR2) bands at millimeter and centimeter wavelengths between 20 and 60 GHz, etc.), cellular sidebands, 6G bands between 100-1000 GHz (e.g., sub-THz, THz, or THF bands), etc.), other centimeter or millimeter wave frequency bands between 10-300 GHz (e.g., a short range wireless data transfer band that supports in-band full duplex communications such as a band between around 57 GHz and 64 GHZ), a near-field communications (NFC) band (e.g., at 13.56 MHz), satellite navigations bands (e.g., an L1 global positioning system (GPS) band at 1575 MHz, an L5 GPS band at 1176 MHz, a Global Navigation Satellite System (GLONASS) band, a BeiDou Navigation Satellite System (BDS) band, etc.), an ultra-wideband (UWB) communications band supported by the IEEE 802.15.4 protocol and/or other UWB communications protocols (e.g., a first UWB communications band at 6.5 GHz and/or a second UWB communications band at 8.0 GHz), and/or any other desired communications bands. The communications bands handled by such radio-frequency transceiver circuitry may sometimes be referred to herein as frequency bands or simply as “bands,” and may span corresponding ranges of frequencies. In general, the radio-frequency transceiver circuitry within wireless circuitry 24 may cover (handle) any desired frequency bands of interest.

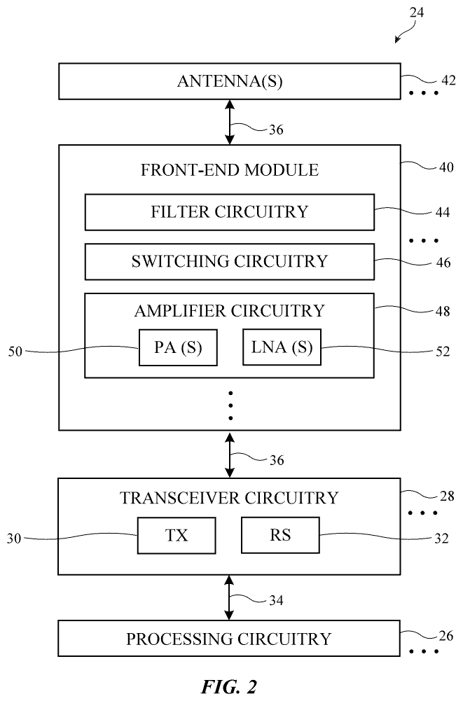

FIG. 2 is a diagram showing illustrative components within wireless circuitry 24. As shown in FIG. 2, wireless circuitry 24 may include processing circuitry such as processing circuitry 26, radio-frequency (RF) transceiver circuitry such as radio-frequency transceiver 28, radio-frequency front-end circuitry such as radio-frequency front-end module (FEM) 40, and antenna(s) 42. Processing circuitry 26 may be coupled to transceiver 28 over baseband path 34. Transceiver 28 may be coupled to antenna 42 via radio-frequency transmission line path 36. Radio-frequency front-end module 40 may be disposed on radio-frequency transmission line path 36 between transceiver 28 and antenna 42. Any block shown in FIG. 2 can be provided with a third order non-linearity cancellation circuit configured to improve the EVM of the overall wireless circuitry 24.

In the example of FIG. 2, wireless circuitry 24 is illustrated as including only a single processing unit 26, a single transceiver 28, a single front-end module 40, and a single antenna 42 for the sake of clarity. In general, wireless circuitry 24 may include any desired number of processing units 26, any desired number of transceivers 28, any desired number of front-end modules 40, and any desired number of antennas 42. Each processing unit 26 may be coupled to one or more transceiver 28 over respective baseband paths 34. Each transceiver 28 may include a transmitter circuit 30 configured to output uplink signals to antenna 42, may include a receiver circuit 32 configured to receive downlink signals from antenna 42, and may be coupled to one or more antennas 42 over respective radio-frequency transmission line paths 36. Each radio-frequency transmission line path 36 may have a respective front-end module 40 disposed thereon. If desired, two or more front-end modules 40 may be disposed on the same radio-frequency transmission line path 36. If desired, one or more of the radio-frequency transmission line paths 36 in wireless circuitry 24 may be implemented without any front-end module disposed thereon.

Radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path such that is coupled to the positive antenna feed terminal on antenna 42. Radio-frequency transmission line path 36 may have a ground transmission line signal path that is coupled to the ground antenna feed terminal on antenna 42. This example is merely illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency antenna signals within device 10 (FIG. 1). Transmission lines in device 10 may include coaxial cables, microstrip transmission lines, stripline transmission lines, edge-coupled microstrip transmission lines, edge-coupled stripline transmission lines, transmission lines formed from combinations of transmission lines of these types, etc. Transmission lines in device 10 such as transmission lines in radio-frequency transmission line path 36 may be integrated into rigid and/or flexible printed circuit boards.

In performing wireless transmission, processing circuitry 26 may provide baseband signals to transceiver 28 over baseband path 34. Transceiver 28 may further include circuitry for converting the baseband signals received from processing circuitry 26 into corresponding radio-frequency signals. For example, transceiver circuitry 28 may include mixer circuitry for up-converting (or modulating) the baseband signals to radio-frequencies prior to transmission over antenna 42. Transceiver circuitry 28 may also include digital-to-analog converter (DAC) and/or analog-to-digital converter (ADC) circuitry for converting signals between digital and analog domains. Transceiver 28 may use transmitter (TX) 30 to transmit the radio-frequency signals over antenna 42 via radio-frequency transmission line path 36 and front-end module 40. Antenna 42 may transmit the radio-frequency signals to external wireless equipment by radiating the radio-frequency signals into free space.

In performing wireless reception, antenna 42 may receive radio-frequency signals from the external wireless equipment. The received radio-frequency signals may be conveyed to transceiver 28 via radio-frequency transmission line path 36 and front-end module 40. Transceiver 28 may include circuitry such as receiver (RX) 32 for receiving signals from front-end module 40 and for converting the received radio-frequency signals into corresponding baseband signals. For example, transceiver 28 may include mixer circuitry for down-converting (or demodulating) the received radio-frequency signals to baseband frequencies prior to conveying the received signals to processing circuitry 26 over baseband path 34.

Front-end module (FEM) 40 may include radio-frequency front-end circuitry that operates on the radio-frequency signals conveyed (transmitted and/or received) over radio-frequency transmission line path 36. FEM 40 may, for example, include front-end module (FEM) components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifier circuits 50 and/or one or more low-noise amplifier circuits 52), impedance matching circuitry (e.g., circuitry that helps to match the impedance of antenna 42 to the impedance of radio-frequency transmission line 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other desired circuitry that operates on the radio-frequency signals transmitted and/or received by antenna 42. Each of the front-end module components may be mounted to a common (shared) substrate such as a rigid printed circuit board substrate or flexible printed circuit substrate. If desired, the various front-end module components may also be integrated into a single integrated circuit chip.

Filter circuitry 44, switching circuitry 46, amplifier circuitry 48, and other circuitry may be disposed along radio-frequency transmission line path 36, may be incorporated into FEM 40, and/or may be incorporated into antenna 42 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antenna 42 over time.

Transceiver 28 may be separate from front-end module 40. For example, transceiver 28 may be formed on another substrate such as the main logic board of device 10, a rigid printed circuit board, or flexible printed circuit that is not a part of front-end module 40. While control circuitry 14 is shown separately from wireless circuitry 24 in the example of FIG. 1 for the sake of clarity, wireless circuitry 24 may include processing circuitry that forms a part of processing circuitry 18 and/or storage circuitry that forms a part of storage circuitry 16 of control circuitry 14 (e.g., portions of control circuitry 14 may be implemented on wireless circuitry 24). As an example, processing circuitry 26 and/or portions of transceiver 28 (e.g., a host processor on transceiver 28) may form a part of control circuitry 14. Control circuitry 14 (e.g., portions of control circuitry 14 formed on processing circuitry 26, portions of control circuitry 14 formed on transceiver 28, and/or portions of control circuitry 14 that are separate from wireless circuitry 24) may provide control signals (e.g., over one or more control paths in device 10) that control the operation of front-end module 40.

Transceiver circuitry 28 may include wireless local area network transceiver circuitry that handles WLAN communications bands (e.g., Wi-Fi® (IEEE 802.11) or other WLAN communications bands) such as a 2.4 GHz WLAN band (e.g., from 2400 to 2480 MHz), a 5 GHZ WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network transceiver circuitry that handles the 2.4 GHz Bluetooth® band or other WPAN communications bands, cellular telephone transceiver circuitry that handles cellular telephone bands (e.g., bands from about 600 MHz to about 5 GHZ, 3G bands, 4G LTE bands, 5G New Radio Frequency Range 1 (FR1) bands below 10 GHz, 5G New Radio Frequency Range 2 (FR2) bands between 20 and 60 GHz, etc.), near-field communications (NFC) transceiver circuitry that handles near-field communications bands (e.g., at 13.56 MHz), satellite navigation receiver circuitry that handles satellite navigation bands (e.g., a GPS band from 1565 to 1610 MHz, a Global Navigation Satellite System (GLONASS) band, a BeiDou Navigation Satellite System (BDS) band, etc.), ultra-wideband (UWB) transceiver circuitry that handles communications using the IEEE 802.15.4 protocol and/or other ultra-wideband communications protocols, and/or any other desired radio-frequency transceiver circuitry for covering any other desired communications bands of interest.

Wireless circuitry 24 may include one or more antennas such as antenna 42. Antenna 42 may be formed using any desired antenna structures. For example, antenna 42 may be an antenna with a resonating element that is formed from loop antenna structures, patch antenna structures, inverted-F antenna structures, slot antenna structures, planar inverted-F antenna structures, helical antenna structures, monopole antennas, dipoles, hybrids of these designs, etc. Two or more antennas 42 may be arranged into one or more phased antenna arrays (e.g., for conveying radio-frequency signals at millimeter wave frequencies). Parasitic elements may be included in antenna 42 to adjust antenna performance. Antenna 42 may be provided with a conductive cavity that backs the antenna resonating element of antenna 42 (e.g., antenna 42 may be a cavity-backed antenna such as a cavity-backed slot antenna).

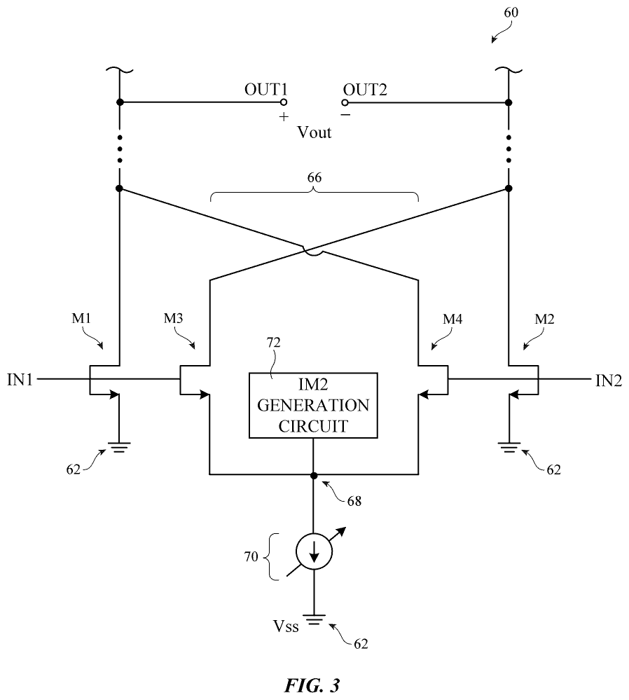

FIG. 3 is a diagram of differential circuitry such as differential circuitry 60 that can be part of wireless circuitry 24. Differential circuitry 60 of FIG. 3 can represent a power amplifier 50 in the transmit path, a variable gain amplifier (VGA) in the transmit path, a low noise amplifier 52 in the receive path, a mixer or modulator in the transmit path, a mixer or demodulator in the receive path, a gain block in the transmit or receive path, a component in the front-end module 40 or transceiver 28, and/or other component along transmission line path 36. Scenarios in which differential circuitry 60 represents a radio-frequency amplifier or a mixer is sometimes described herein as an example. Differential circuitry 60 can thus sometimes be referred to as amplifier or mixer circuitry.

As shown in FIG. 3, differential circuitry 60 can include at least transistors M1 and M2. Transistors M1 and M2 may be n-type (n-channel) transistors such as n-type metal-oxide-semiconductor (NMOS) devices. Transistor M1 may have a source terminal coupled to a ground power supply line 62 (e.g., a ground line on which ground power supply voltage Vss is provided), a drain terminal, and a gate terminal that is coupled to a first input terminal IN1. Transistor M2 may have a source terminal coupled to ground power supply line 62, a drain terminal, and a gate terminal that is coupled to a second input terminal IN2. Input terminals IN1 and IN2 serve collectively as a differential input port of circuitry 60. A radio-frequency signal can be received at the differential input of circuitry 60. Transistors M1 and M2 are thus sometimes referred to as “input” transistors. The terms “source” and “drain” terminals used to refer to current-conveying terminals in a transistor may be used interchangeably and are sometimes referred to as “source-drain” terminals. Thus, the source terminal of transistor M1 can sometimes be referred to as a first source-drain terminal, and the drain terminal of transistor M1 can be referred to as a second source-drain terminal (or vice versa).

The drain terminal of the first input transistor M1 may be coupled to a first output terminal OUT1, whereas the drain terminal of the second input transistor M2 may be coupled to a second output terminal OUT2. Output terminals OUT1 and OUT2 may serve collectively as a differential output port of differential circuitry 60. A differential output voltage Vout can be provided across the output terminals OUT1 and OUT2. In general, a radio-frequency signal can be provided or generated at the differential input port and/or the differential output port of circuitry 60. Differential circuitry 60 of this type is therefore sometimes referred to as radio-frequency (RF) circuitry.

If desired, differential circuitry 60 can optionally include cascode transistors coupled between the input transistors and the output terminals. For example, a first cascode transistor can be coupled in series between input transistor M1 and output terminal OUT1, whereas a second cascode transistor can be coupled in series between input transistor M2 and output terminal OUT2. Such cascode transistors, sometimes referred to as a cascode amplifier stage, can be included to increase the output impedance of circuitry 60 and can optionally be used to provide different gain steps (e.g., by selectively adjusting the drive strength of the cascode transistors). In general, one or more transistors, capacitors, resistors, inductors, transformers, and/or other load components can be coupled to the output terminals OUT1 and OUT2.

Differential circuitry 60 can further include a third transistor M3, a fourth transistor M4, and a current source 70. Transistor M3 may have a gate terminal coupled to the gate terminal of input transistor M1, a source terminal coupled to a tail node 68, and a drain terminal that is cross-coupled to output terminal OUT2. Transistor M4 may have a gate terminal coupled to the gate terminal of input transistor M2, a source terminal coupled to tail node 68, and a drain terminal that is coupled to output terminal OUT1. Current source 70 may be coupled between tail node 68 shorted to the source terminals of transistors M3 and M4 and ground line 62. Current source 70 can be a fixed current source or an adjustable current source (e.g., a current source that can be selectively activated and deactivated). Additionally, transistors M3 and M4 may exhibit parasitic gate-to-drain capacitance on the output terminals OUT1 and OUT2 of circuitry 60. Such gate-to-drain capacitance of transistors M3 and M4 can optionally be configured to serve as capacitance neutralization capacitors for circuitry 60 and can help obviate the need for separate dedicated neutralization capacitors. In other words, cross-coupled transistors M3 and M4 can provide parasitic gate-to-drain capacitance that neutralizes the parasitic capacitance associated with input transistors M1 and M2. The cross-coupled transistors M3 and M4 are therefore sometimes referred to and defined herein as “capacitance neutralization” transistors. This can help reduce circuit area and cost while preserving enhanced reverse isolation.

The performance of a radio-frequency circuit is sometimes quantified by a parameter known as error vector magnitude (EVM). Ideally, a signal transmitted by a radio-frequency circuit would have signal modulation constellation points at certain ideal locations on a complex plane. Due to design imperfections, distortion, spurious signals, and/or noise, however, the actual constellation points often deviate from the ideal locations. Error vector magnitude is a measure of how far the actual points deviate from the ideal locations.

Differential circuits such as amplifiers, in general, have a linear operating range and a non-linear operating range. To avoid signal distortion, amplifiers are often operated in the linear range. When operated in the non-linear range, the ratio of input power to output power may not be constant. Thus, as the input signal amplitude increases, a disproportionate increase in the output signal amplitude may occur. This unwanted additional amplitude modulation due to the non-linear characteristics of the amplifier is sometimes referred to as amplitude modulation to amplitude modulation (AMAM) distortion. Similar to the output signal amplitude, the output phase of an amplifier may change disproportionately as the input signal amplitude increases. This unwanted additional amount of phase modulation due to the non-linear characteristics of the amplifier is sometimes referred to as amplitude modulation to phase modulation (AMPM) distortion.

In accordance with an embodiment, differential circuitry 60 can further be provided with a second order intermodulation (IM2) generation circuit 72 coupled to the tail (source) node 68 of the capacitance neutralization transistors M3 and M4. As its name suggest, IM2 generation circuit 72 can produce second order intermodulation (IM2) signal components, which can be injected at tail node 68. Second order intermodulation generation circuit 72 is thus sometimes referred to herein as an IM2 injection circuit. The injected IM2 signal components can then be transformed, via the non-linearity of the capacitance neutralization transistors M3 and M4, into third order non-linearity components that are out-of-phase with those of input transistors M1 and M2 to help cancel out the overall third order non-linearity of differential circuitry 60. The IM2 generation/injection circuit 72 and the cross-coupled (capacitance neutralization) transistors M3 and M4 are therefore sometimes referred to collectively herein as a third order non-linearity cancellation circuit 66.

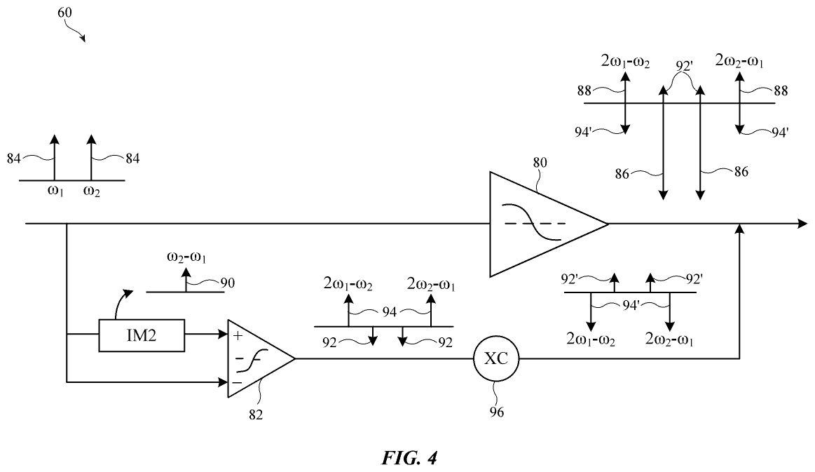

FIG. 4 is a diagram illustrating third order non-linearity cancellation. As shown in FIG. 4, amplifier block 80 represents the amplification function of input transistors M1 and M2, whereas amplifier block 82 represents the amplification function of third order non-linearity cancellation circuit 66. Consider a scenario in which a two-tone signal (e.g., see signals 84 at angular frequencies ω₁ and ω₂) is provided at the input of differential circuitry 60. In general, intermodulation distortion arises when at least two signals of different frequencies are applied to a non-linear circuit and when the amplitude modulation or mixing (multiplication) of the two signals when their sum is raised to a power greater than one generates intermodulation products that are not just at harmonic frequencies (integer multiples) of either input signal but also at the sum and differences of the input signal frequencies and also at sums and differences of multiples of those frequencies. Here, the input signals 84 being fed through amplification block 80 might generate inverted signals 86 at frequencies ω₁ and ω₂ but can also generate third order intermodulation (IM3) products at (2ω₁−ω₂) and (2ω₂−ω₁), as indicated by signals 88. If care is not taken, these IM3 signals 88 can degrade the signals of interest 86. In particular, if the difference between ω₁ and ω₂ is relatively small, then the IM3 components generated at (2ω₁−ω₂) and (2ω₂−ω₁) can appear in the vicinity of ω₁ and ω₂, as shown in FIG. 4. The magnitude of these IM3 tones (see the third order tones 88 appearing on either side of the two signal tones 86) directly contribute to third order intermodulation distortion (IMD3).

In the example of FIG. 4, the IM2 generation circuit 72 can generate a second order intermodulation term (IM2) 90 at frequency (ω₂−ω₁). In accordance with an embodiment, the two signal tones 84 can, when fed through amplification block 82 of circuit 66, be mixed with a second order intermodulation (IM2) product 90 generated at frequency (ω₂−ω₁) to generate corresponding products 94 at frequencies (2ω₁−ω₂) and (2ω₂−ω₁). The original two-tone signal 84 will result in a two-tone signal 92 at ω₁ and ω₂. The cross-coupling of transistors M3 and M4 with the input transistors M1 and M2 is represented by cross-coupling block 96 in FIG. 4 and thus inverts the signals (see, e.g., inverted signals 92′ and 94′). As shown in FIG. 4, the inverted products 94′ can be fed to the output of circuitry 60 for destructively cancelling the IM3 products 88 and are therefore sometimes referred to as third order intermodulation (IM3) cancelling signals. Third order non-linearity cancellation circuit 66 is thus sometimes referred to as a linearization circuit or linearizer. A “non-linearity cancellation” circuit can thus refer to and be defined herein as a circuit that at least partially cancels out intermodulation signals such as IM3 terms produced from the input transistors.

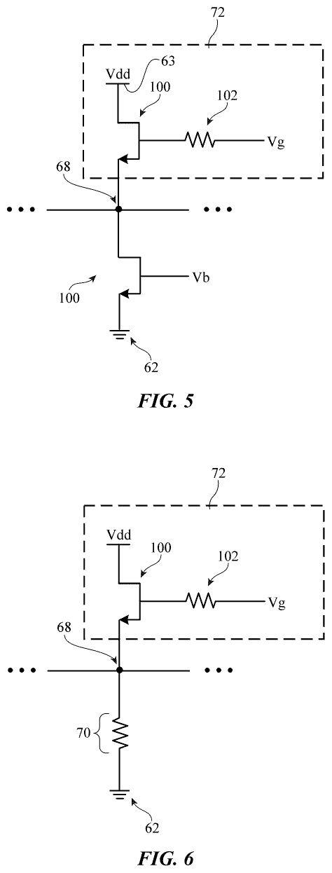

FIG. 5 is a circuit diagram of an illustrative IM2 generation circuit 72 in accordance with some embodiments. As shown in FIG. 5, IM2 generation circuit 72 can include an n-type transistor 100 (e.g., an NMOS transistor). Transistor 100 may have a source terminal coupled to tail node 68, a drain terminal coupled to a positive power supply line 63 (e.g., a power supply terminal on which a positive power supply voltage Vdd is provided), and a gate terminal configured to receive a gate voltage Vg via gate resistor 102. In particular, gate voltage Vg may be set to a voltage level that biases transistor 100 in a weak inversion mode of operation.

For instance, the gate voltage Vg can be set such that the gate-to-source voltage across transistor 100 is around or below a threshold voltage Vth of transistor 100. This weak inversion mode is thus sometimes referred to as a subthreshold mode. When biased in the weak inversion (subthreshold) mode, transistor 100 is either fully deactivated or barely activated such that any drain or leakage current flowing through transistor 100 is exponentially dependent on gate voltage Vg. Gate voltage Vg can be fixed or can be dynamically adjusted. In contrast, the drain current variation of a transistor in strong inversion is linearly dependent on its gate voltage. In the differential mode of operation, the tail node 68 behaves as a virtual ground node. A “virtual ground” can refer to a fixed reference point for differential signals despite not being physically connected to a ground terminal. Thus, IM2 generation circuit 72 being coupled to the virtual ground tail node 68 does not affect the differential mode operation of differential circuitry 60.

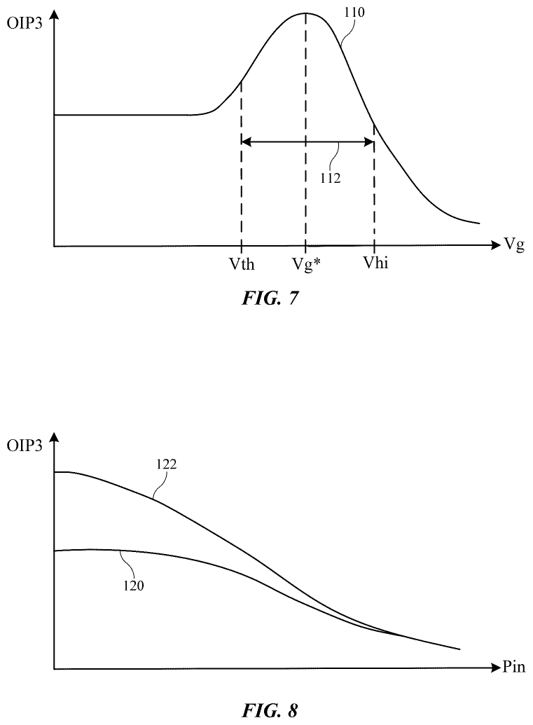

FIG. 7 is a diagram plotting third order intercept point as a function of gate voltage Vg that is provided to the gate terminal of transistor 100. In particular, FIG. 7 plots the “output” third-order intercept point or OIP3, which is a parameter used to characterize the linearity of an electronic circuit such as differential circuitry 60, as a function of gate voltage Vg. The output third order intercept point can represent the output power level Pout at which the third-order intermodulation products generated by circuitry 60 reach the same level as the desired output signal in a two-tone scenario. In general, it is desirable to increase the OIP3. As shown in FIG. 7, the OIP3 curve 110 can exhibit elevated levels within a range 112 near the threshold voltage Vth of transistor 100. For instance, gate voltage Vg can be set to a value Vg* configured to produce a peak OIP3 (see, e.g., corresponding to a peak of profile 110). The optimal range 112 may extend from voltage Vlow to Vhi, where Vg* sits somewhere between Vlow and Vhi. Voltage Vlow may be higher, lower, or around threshold voltage Vth of transistor 100. Voltage Vhi may present a voltage level at which gate voltages exceeding this level will lead to a degradation in OIP3. High Vg levels (e.g., voltage levels above Vhi) may correspond to transistor 100 being biased in a strong inversion or saturation mode of operation. Although FIG. 7 illustrates output IP3, a similar improvement can be achieved when plotting “input” third-order intercept points (IIP3) for differential circuitry 60.

The term “activate” with respect to a switch (or transistor) may refer to or be defined herein as an action that places the switch in an “on” or low-impedance state such that the two terminals of the switch are electrically connected to conduct current. Activating a switch can sometimes be referred to as turning on or closing a switch. The term “deactivate” with respect to a switch (or transistor) may refer to or be defined herein as an action that places the switch in an “off” or high-impedance state such that the two terminals of the switch/transistor are electrically disconnected with minimal leakage current. Deactivating a switch can sometimes be referred to as turning off or opening a switch.

In the example of FIG. 5, current source 70 can be implemented as an n-type transistor (e.g., an NMOS transistor). In particular, the n-type current source transistor 70 can have a drain terminal coupled to tail node 68, a source terminal coupled to ground line 62, and a gate terminal configured to receive a gate bias voltage Vb. The gate bias voltage Vb can be adjusted to bias the cross-coupled transistors M3 and M4 at various operating points. The third order non-linearity cancellation circuit 66 may operate as follows. As the input signal (power) increases, the current flowing through transistor 72 and transistor 70 increases, which will deactivate the cross-coupled transistors M3 and M4. Transistor 100 can be configured to steer current away from the cross-coupled transistors M3 and M4 at high power levels. As the cross-coupled transistors M3 and M4 are turned off at high signal power levels, the differential gain of circuitry 60 will increase, thus compensating for any undesired AMAM compression. Moreover, at high signal power levels, the gate-to-source capacitance of the input transistors M1 and M2 increases while the gate-to-source capacitance of the cross-coupled transistors M3 and M4 decreases, which can lead to reduction in AMPM distortion. The use of gate resistor 102 can help provide control of the IM2 signal produced from circuit 72. Gate resistor 102 is optional and can be omitted, if desired. Transistor 100 can produce IM2 signals and is sometimes referred to herein as a second order intermodulation injection transistor.

The example of FIG. 5 in which IM2 generation circuit 72 includes an n-type transistor 100 is illustrative. In general, transistor 100 should have the same channel type as the input transistors M1 and M2. Thus, in another embodiment where differential circuitry 60 has p-type input transistors M1 and M2, then transistor 100 within IM2 generation circuit 72 can be implemented as a p-type transistor biased in the weak inversion mode.

The example of FIG. 5 in which current source 70 is implemented as a transistor is also illustrative. FIG. 6 is a circuit diagram showing how current source 70 can be implemented as a fixed resistor. In particular, fixed resistor 70 can have a first terminal coupled to tail node 68 and a second terminal coupled to ground line 62. At high power levels, the IR (voltage) drop across tail resistor 70 will increase, which will then deactivate the cross-coupled transistors M3 and M4. As the cross-coupled transistors M3 and M4 are turned off at high signal power levels, the differential gain of circuitry 60 will increase, thus compensating for any undesired AMAM compression. Moreover, at high signal power levels, the gate-to-source capacitance of the input transistors M1 and M2 increases while the gate-to-source capacitance of the cross-coupled transistors M3 and M4 decreases, which can lead to reduction in AMPM distortion.

FIG. 8 is a diagram showing how third order intercept point can be improved via third order non-linearity cancellation in accordance with some embodiments. In particular, FIG. 8 plots the output third-order intercept point or OIP3 of differential circuitry 60. As shown in FIG. 8, curve 120 represents the OIP3 profile for circuitry 60 when cancellation circuit 66 is deactivated or omitted. For example, cancellation circuit 66 can be selectively deactivated by shutting down the adjustable current source 70. In the example of FIG. 5, the current source 70 can be disabled by driving bias voltage Vb down to ground (e.g., to selectively disable transistors M3 and M4 and thus deactivate the third order non-linearity cancellation circuit 66). Alternatively, bias voltage Vb can be driven to a high voltage to selectively enable transistors M3 and M4 and thus activate the third order non-linearity cancellation circuit 66. In contrast, curve 122 in FIG. 8 may represent the OIP3 profile for differential circuitry 60 when cancellation circuit 66 has been activated or switched into use. Curve 122 exhibits improved or greater OIP3 levels compared to curve 120. Although FIG. 8 shows output IP3, a similar improvement can be achieved when plotting “input” third-order intercept points (IIP3) for differential circuitry 60.

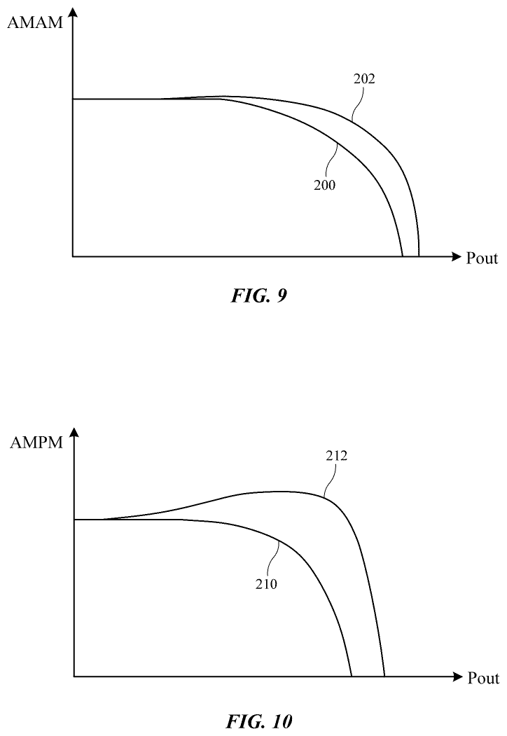

FIG. 9 is a diagram showing how amplitude modulation to amplitude modulation (AMAM) distortion can be reduced via third order non-linearity cancellation in accordance with some embodiments. In particular, FIG. 9 plots normalized AMAM, which is a function of the difference between gain at a low power level and gain at an operating power level as a function of output power level Pout. Curve 200 may represent the normalized AMAM profile with third order non-linearity cancellation circuit 66 entirely disabled, whereas curve 202 may represent the normalized AMAM profile with third order non-linearity cancellation circuit 66 enabled. As shown in FIG. 9, activation of cancellation circuit 66 can help reduce gain compression at higher power levels, which improves AMAM performance.

FIG. 10 is a diagram showing how amplitude modulation to phase modulation (AMPM) distortion can be reduced via third order non-linearity cancellation in accordance with some embodiments. In particular, FIG. 10 plots normalized AMPM, which is a function of the difference between phase at a low power level and phase at an operating power level as a function of output power level Pout. Curve 210 may represent the normalized AMPM profile with third order non-linearity cancellation circuit 66 entirely disabled, whereas curve 212 may represent the normalized AMPM profile with third order non-linearity cancellation circuit 66 enabled. As shown in FIG. 10, activation of cancellation circuit 66 can help reduce phase compression at higher power levels, which improves AMPM performance.

The methods and operations described above in connection with FIGS. 1-10 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 and/or wireless communications circuitry 24 of FIG. 1). The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of device 10 (e.g., processing circuitry in wireless circuitry 24, processing circuitry 18 of FIG. 1, etc.). The processing circuitry may include microprocessors, application processors, digital signal processors, central processing units (CPUs), application-specific integrated circuits with processing circuitry, or other processing circuitry.

The foregoing is merely illustrative and various modifications can be made to the described embodiments. The foregoing embodiments may be implemented individually or in any combination.

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

What is claimed is:

1. Circuitry comprising:
a first input transistor having a gate terminal;
a first capacitance neutralization transistor having a gate terminal shorted to the gate terminal of the first input transistor and having a source terminal coupled to a tail node; and
a second order intermodulation (IM2) generation circuit configured to produce second order intermodulation (IM2) signals at the tail node.

2. The circuitry of claim 1, further comprising:
a second input transistor having a gate terminal; and
a second capacitance neutralization transistor having a gate terminal shorted to the gate terminal of the second input transistor, a drain terminal coupled to the first input transistor, and a source terminal coupled to the tail node.

3. The circuitry of claim 2, further comprising:
a current source coupled to the tail node.

4. The circuitry of claim 3, wherein the current source comprises a transistor configured to receive a fixed bias voltage.

5. The circuitry of claim 3, wherein the current source comprises a transistor configured to receive an adjustable bias voltage.

6. The circuitry of claim 5, wherein the adjustable bias voltage is set to a first value for selectively enabling the first and second capacitance neutralization transistors and is set to a second value for selectively disabling the first and second capacitance neutralization transistors.

7. The circuitry of claim 3, wherein the current source comprises a resistor.

8. The circuitry of claim 3, wherein the second order intermodulation generation circuit comprises a transistor having a source terminal coupled to the tail node and having a drain terminal coupled to a positive power supply line.

9. The circuitry of claim 8, wherein the transistor further includes a gate terminal configured to receive a gate voltage that biases the transistor in a weak inversion mode.

10. The circuitry of claim 9, wherein the second order intermodulation generation circuit further comprises a resistor coupled at the gate terminal of the transistor and configured to control the second order intermodulation signals produced by the second order intermodulation generation circuit.

11. Circuitry comprising:
a first input transistor configured to receive a radio-frequency signal;
a second input transistor configured to receive the radio-frequency signal;
a pair of transistors cross-coupled with the first and second input transistors; and
a second order intermodulation (IM2) generation circuit coupled to a virtual ground node between the pair of transistors.

12. The circuitry of claim 11, wherein:
a first transistor in the pair of transistors has a gate terminal shorted to a gate terminal of the first input transistor and has a drain terminal coupled to the second input transistor; and
a second transistor in the pair of transistors has a gate terminal shorted to a gate terminal of the second input transistor and has a drain terminal coupled to the first input transistor.

13. The circuitry of claim 11, further comprising:
an adjustable current source coupled to the virtual ground node.

14. The circuitry of claim 11, further comprising:
a resistor coupled between the virtual ground node and a ground power supply line.

15. The circuitry of claim 11, wherein the second order intermodulation generation circuit comprises a transistor biased in a weak inversion mode.

16. The circuitry of claim 15, wherein the transistor of the second order intermodulation generation circuit is configured to receive a gate voltage having a value configured to optimize a third order intercept point for the circuitry.

17. The circuitry of claim 15, wherein the second order intermodulation generation circuit further comprises a resistor coupled at a gate terminal of the transistor and configured to control second order intermodulation signals produced by the second order intermodulation generation circuit.

18. The circuitry of claim 15, wherein the first input transistor has a first channel type and wherein the transistor of the second order intermodulation generation circuit has a second channel type identical to the first channel type.

19. Amplifier circuitry comprising:
a first transistor having a gate terminal and a source-drain terminal;
a second transistor having a gate terminal and a source-drain terminal;
a third transistor having a gate terminal shorted to the gate terminal of the first transistor, a first source-drain terminal coupled to the source-drain terminal of the second transistor, and a second source-drain terminal coupled to a tail node;
a fourth transistor having a gate terminal shorted to the gate terminal of the second transistor, a first source-drain terminal coupled to the source-drain terminal of the first transistor, and a second source-drain terminal coupled to the tail node; and
a second order intermodulation (IM2) injection transistor having a first source-drain terminal coupled to the tail node and having a second source-drain terminal coupled to a power supply line.

20. The amplifier circuitry of claim 19, further comprising:
a current source transistor or a resistor coupled to the tail node.
